(19) United States
(12) Patent Application Publication
(10) Pub. No.: US 2003/0183929 A1
(43) Pub. Date: Oct. 2, 2003

(54) System and method for reconditioning electronic components

(76) Inventor: Igor Boguslavsky, Glencoe, IL (US)

Correspondence Address: KATTEN MUCHIN ZAVIS ROSENMAN, Attention: Patent Administrator, 525 West Monroe Street, Suite 1600, Chicago, IL, 60661-3693, US

(21) Appl. No.: 10/109,278

(22) Filed: Mar. 28, 2002

(51) Int. Cl. H01L 23/48

(52) U.S. Cl. 257/734

(57) ABSTRACT

Briefly, the present invention relates to a method and system for reconditioning leads on various IC package configurations, such as QFP, TSOP, SOIC, PLCC, SOJ and various other package configurations, as well as damaged spheres on BGA-type components, which provides increased reliability relative to known methods for reconditioning such components. The method and system in accordance with the present invention reconditions damaged leads and spheres on ICs and restores the leads or spheres to the original IC packaging standard, such as JEDEC standards. In particular, the method and system in accordance with the present invention, after an initial inspection, thermally conditions components to remove any moisture that may later result in a failure mode. Thermal conditioning is done in accordance with the original packaging standard, such as the JEDEC standard. By removing moisture from the IC, failure modes which cannot be detected by mechanical strength tests are virtually eliminated, thus significantly improving the reliability of such reconditioned components. For non-surface-mount components, leads are reworked in accordance with the original packaging standards. Similarly, for BGA-type ICs, damaged spheres are re-balled in accordance with the original packaging standards. All reconditioning is performed in an electrostatic discharge (ESD) safe environment. Prior to shipping, all components are optionally baked again, packaged in a packaging configuration, such as tape and reel, trays or tubes and vacuum sealed for reshipment to the customer. By removing moisture from the components, the components are reconditioned to the original packaging standard, such as the JEDEC standard, thus providing significantly increased reliability relative to known methods for reconditioning such components.

### BACKGROUND OF THE INVENTION

1. Field of the Invention

The present invention relates to a method and system for reconditioning electronic components which have been scrapped because of defects in the component external leads, or spheres in the case of components configured in a ball grid array (BGA), and more particularly to a method and system for reconditioning the external leads and spheres of such components to meet the original packaging standards, such as JEDEC standards, which reduces the number and cost associated with scrapping the electronic components, while at the same time providing reconditioned electronic components with a relatively high level of reliability.

2. Description of the Prior Art

Electronic components and, more specifically, integrated circuits (ICs) are available in a variety of package configurations, including a quad-flat package (QFP), thin small outline package (TSOP), small outline integrated circuit (SOIC), plastic leaded chip carrier (PLCC), small outline J-lead (SOJ), and ball grid array (BGA). With the exception of BGA components, all of the integrated package configurations come with external leads for connection to a printed circuit board (PCB) in which the leads are either plugged into a socket that has been soldered to a PCB or directly soldered to the PCB. BGA components, on the other hand, are surface-mount components which include spheres that are soldered directly to bonding pads on a printed circuit board. Such leads and spheres (referred to herein as electrical connections to mean either leads or spheres individually or collectively) are known to be damaged during the process of being connected to a PCB.

Although the number of damaged electrical connections is known to be relatively low—for example, less than one percent—the cost of scrapping damaged components can be quite substantial. As such, manufacturers are no longer known to scrap ICs in which the electrical connections have been damaged. Within the last few years, manufacturers have been known to recondition damaged electrical connections.

Initially, manufacturers were known to manually recondition leads using various tools, such as magnifiers, tweezers, artists' knives and other semi-automatic devices. Some devices actually required video magnification in order to recondition component leads. Such reconditioning was known to be very time consuming taking, for example, up to twenty minutes or more per IC. Due to the volume of ICs with damaged leads, component reconditioning by a manufacturer has been known to become impractical. Another consideration here is that manual reconditioning of ICs does not produce levels of precision needed for automated high speed assembly.

BGA-type ICs pose a different problem to manufacturers. In particular, damaged spheres on a BGA component normally need to be replaced by a process called re-balling. Due to the complexity of re-balling, BGA-type ICs, ICs with damaged spheres were simply scrapped and recycled.

Due to the problems associated with the reconditioning of leaded ICs with external leads and BGA-type ICs coupled with the cost of scrapping such damaged components, manufacturers are now known to outsource such reconditioning to a growing industry of component reconditioning service providers. Such component reconditioning service providers are known to accept bulk ICs as well as ICs on PCBs for reconditioning. ICs with damaged leads or spheres in bulk or mounted on PCBs are demounted and conditioned. The component reconditioning service providers have been able to reduce the cost of rework of damaged leads and reball the spheres in BGA-type ICs to make it cost-effective for manufacturers to have the damaged components reconditioned. For example, as discussed in “Component Reconditioning Adds to Bottom Line”, by Joyce Laird, Surface Mount Technology magazine, November 2001, machinery has been developed and is being used by component reconditioning service providers to re-form damaged external leads of ICs in various packaging configurations. Although not all ICs with damaged external leads can be reconditioned by such component reconditioning service providers, enough of the damaged ICs can be recovered to make the reconditioning of ICs with damaged external leads by component reconditioning service providers cost-effective. The use of machines in the process for re-forming the leads eliminates operator subjectivity, which can result in further damage and overworking of the leads.

Methods have also been developed for re-balling BGA-type ICs. As discussed in “Re-balling Reclaimed BGAs”, by William J. Casey, Circuits Assembly magazine, July 1999, various methods have been developed for removing damaged spheres from BGA ICs and replacing them with new spheres. These methods include a stencil method, an automated dispensing method, a high-purity copper braid method and a dry soldering method. In all of the methods, BGA ICs are removed from the PCB using the manufacturers' recommended re-flow profile to maintain the integrity of the package during component removal. The damaged spheres may be re-balled using one of the processes discussed above. Although there are mechanical tests performed on the re-balled spheres, such re-balled spheres are still known to fail. Thus, there is a need for a method and system for reconditioning components, including re-balling damaged spheres on BGA ICs, that is more reliable and that has a reduced failure rate relative to known processes for reconditioning such components.

### SUMMARY OF THE INVENTION

Briefly, the present invention relates to a method and system for reconditioning leads on various IC package configurations, such as QFP, TSOP, SOIC, PLCC, SOJ and various other package configurations, as well as damaged spheres on BGA-type components, which provides increased reliability relative to known methods for reconditioning such components. The method and system in accordance with the present invention reconditions damaged leads and spheres on ICs and restores the leads or spheres to the original IC packaging standard, such as JEDEC standards. In particular, the method and system in accordance with the present invention, after an initial inspection, thermally conditioning conditions components to remove any moisture that may later result in a failure mode. Thermal conditioning is done in accordance with the original packaging standard, such as the JEDEC standard. By removing moisture from the IC, failure modes which cannot be detected by mechanical strength tests are virtually eliminated, thus significantly improving the reliability of such reconditioned components. For non-surface-mount components, leads are reworked in accordance with the original packaging standards. Similarly, for BGA-type ICs, damaged spheres are re-balled in accordance with the original packaging standards. All reconditioning is performed in an electrostatic discharge (ESD) safe environment. Prior to shipping, all components are optionally baked again, packaged in a standard packaging configuration, such as tape and reel, trays or tubes and vacuum sealed for reshipment to the customer. By removing moisture from the components, the components are reconditioned to the original packaging standard, such as the JEDEC standard, thus providing significantly increased reliability relative to known methods for reconditioning such components.

### DESCRIPTION OF THE DRAWINGS

These and other advantages of the present invention will be readily understood with reference to the following specification and attached drawing, wherein:

FIG. 1A is a process flow diagram of the method in accordance with the present invention.

FIG. 2A illustrates exemplary inspection criteria for a damaged IC having gull-wing-type external leads.

FIG. 2B is similar to FIG. 2A, except that it is for damaged components with J-leads.

FIG. 2C illustrates exemplary inspection criteria for the spheres on BGA-type ICs.

FIG. 3 illustrates an exemplary solder reflow thermal profile for removing components to be conditioned from printed circuit boards (PCB).

FIG. 4 illustrates an exemplary solder reflow thermal profile for removing BGA components to be conditioned from a PCB.

FIG. 5 illustrates an exemplary solder reflow thermal profile for solder removal from a BGA.

FIG. 6 illustrates an exemplary solder re-flow thermal profile for removing solder from leaded devices.

### DETAILED DESCRIPTION

The present invention relates to a system and method for reconditioning the external leads on leaded electronic components and/or spheres on BGA-type components (individually or collectively “electrical connections”) to restore the leads and/or spheres to the original packaging standards, such as JEDEC standards. In accordance with an important aspect of the invention, as will be discussed in more detail below. Damaged electrical connections are subjected to thermal conditioning to remove any moisture in the component. By removing excess moisture, the reliability of the reconditioned component is significantly increased which prevents failure modes that are normally undetectable by mechanical strength tests, such as shear tests.

Integrated packages made from moisture-permeable materials, such as plastic, are known to result in failure modes due to the moisture content within the IC package at elevated temperatures, which may occur during solder re-flow, as set forth in “Moisture Sensitive Components” by Robert Roland, Surface Mount Technology magazine, October 2000. At elevated temperatures, moisture trapped within the plastic package is known to result in a vapor pressure significant to damage or destroy the device. As such, standards organizations, such as the Joint Solid State Products Engineering Council (JEDEC), have developed various standards for handling such moisture-sensitive components. These standards include the following:

| Standard Name | Title |
|---|---|
| IPC/JEDEC J-STD-020 | Moisture/Re-flow Sensitivity |
| | Classification for Plastic Integrated Circuit |
| | (IC) SMDs |
| IPC/JEDEC J-STD-033 | Standard for Handling, Packaging and |
| | Shipping and Use of Moisture Re-flow |
| | Sensitive SMDs |
| IPC/JEDEC J-STD-035 | Acoustic Microscopy for Non-Hermetic |
| | Encapsulated Electronic Components |
| IPC/9501 | PWB Assembly Process Simulation for |
| | Evaluation of Electronic Components |
| | (Preconditioning IC Components) |
| IPC/9502 | PWB Assembly Soldering Process |
| | Guideline for Electronic Components |
| IPC/9503 | Moisture Sensitivity Classification for |
| | Non-IC Components |
| IPC/9504 | Assembly Process Simulation for |
| | Evaluation of Non-IC Components |
| | (Preconditioning Non-IC Components) |

These standards have been developed for the manufacturer and end user of such moisture-sensitive components. For example, IPC/JEDEC J-STD-033 provides recommendations for handling, packaging and shipping such components, while IPC/JEDEC J-STD-020 provides an estimated floor life for components subjected to specific temperatures and humidity profiles.

Unfortunately, component handling and shelf life standards are known to be ignored in the situation when the component leads or leaded components or spheres on BGA-type ICs have been damaged, for example, during the process of attaching the component to a printed circuit board. Such damaged components are known to be placed in a recycle bin and sent to a component reconditioning service provider for reconditioning. Because the components have moisture-permeable packages, such as plastic packages, such components are subject to the absorption of moisture all of the time. As such, when a component reconditioning service provider receives a batch of components for reconditioning, the moisture content of such component is unknown and will vary drastically according to the time and temperature/humidity profile to which each of the components has been subjected. As mentioned earlier, trapped moisture in such components at elevated temperatures can result in increased vapor pressure within the package, which can damage the component after it has been reconditioned and is being re-soldered to a printed circuit board. In order to avoid such a potential failure mode, the system, in accordance with the present invention, thermally profiles all components in moisture permeable packages to remove moisture content. The components may be optionally thermally profiled before reconditioning and/or optionally thermally profiled again after reconditioning and vacuum sealed in accordance with known packaging standards, such as those discussed above, in order to restore the reconditioned component to the original packaging specification.

The process in accordance with the present invention is suitable for use with various non-surface-mount IC packages-including a quad-flat package (QFP), thin small outline package (TSOP), small outline integrated circuit (SOIC); plastic leaded chip carrier (PLCC) and small outline J-lead (SOJ). The process is amenable for use with surface mount technology (SMT) components, such as ball grid array (BGA) type components.

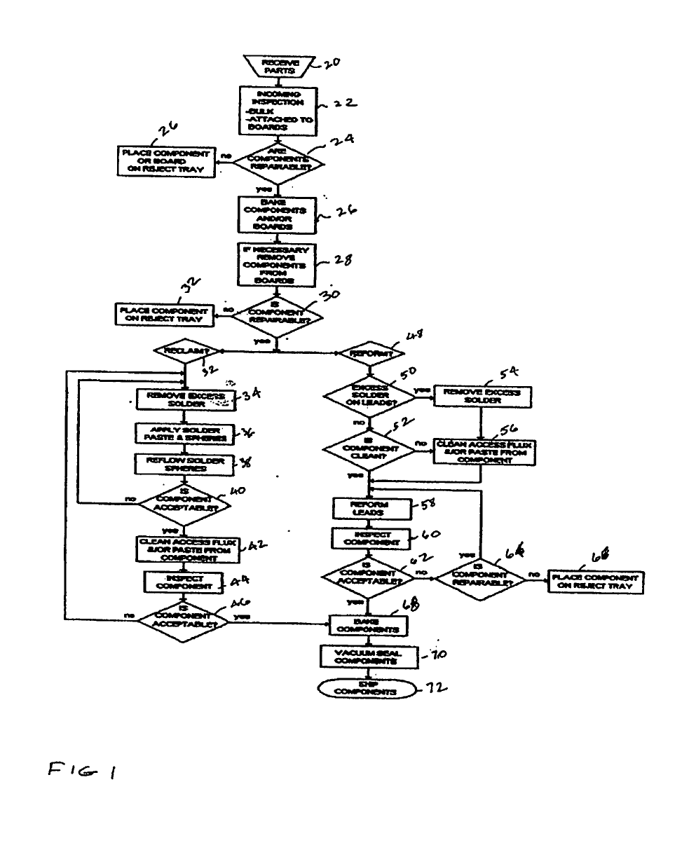

Referring to FIG. 1, a process diagram for the method and system in accordance with the present invention is illustrated. Initially, in step 20, damaged components both in bulk form and attached to printed circuit boards (PCB) are received. These components are normally from scrap/excess or obsolete printed circuit boards and line attrition. The component reconditioning process allows customers to dramatically reduce scrap costs and recover components with long lead times, in short supply, or on allocation.

In order to prevent damage to such incoming damaged components from electrostatic discharge (ESD), such components are handled by ESD-safe equipment and procedures throughout the entire process. The ESD-safe equipment includes anti-static flooring, tables as well as wrist and heel straps, which are inspected on a regular basis and documented in accordance with electronic industry standards, such as ANSI/ESD S20-20-1999.

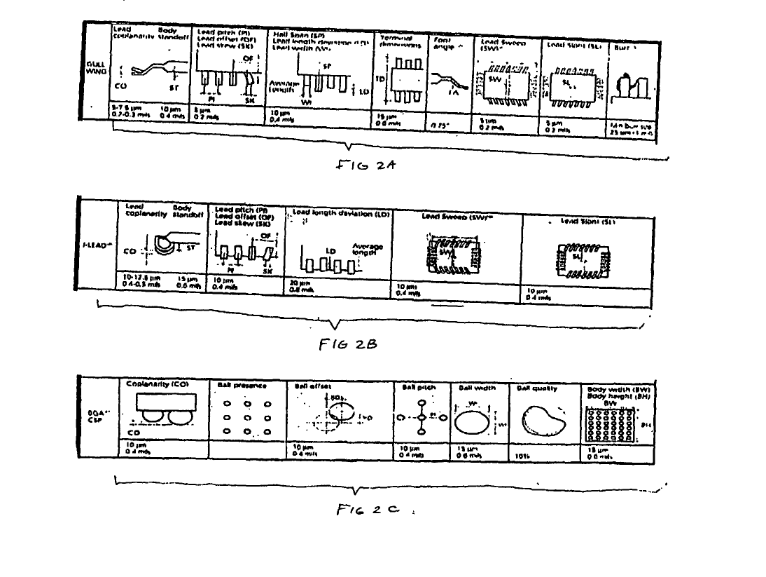

In step 22, all damaged components, whether bulk or still attached to PCBs, are inspected to determine whether the component can be reconditioned. More particularly, loose components and/or components mounted to printed circuit boards may be placed under a magnifier, for example, a Stemi SVII magnifier and inspected in step 24 for: popcorning, splitting/cracking, physical damage, delamination, charring/burning, lifted pads, broken traces, exposed copper within the sphere matrix. The damaged leads and spheres may also be compared with the exemplary criteria, illustrated in FIGS. 2A, 2B and 2C. If the damage to the lead or sphere of a BGA IC fails any of the above-mentioned criteria or falls outside of the range illustrated in FIGS. 2A, 2B or 2C, the components are rejected in step 26 and are considered unsuitable for reconditioning. However, if the lead or sphere of the BGA-type IC does not fail any of the above-mentioned criteria and/or falls within the criteria illustrated in FIGS. 2A, 2B and 2C, a determination is made that the damaged component is amenable to reconditioning.

FIGS. 2A and 2B illustrate exemplary acceptance criteria for non-surface-mount technology (SMT) components. In particular, FIG. 2A illustrates ICs with gull wing-type external leads, while FIG. 2B illustrates ICs with J-lead external leads. FIG. 2C illustrates exemplary criteria for SMT-type components, such as ball grid array (BGA) components.

In accordance with an important aspect of the invention, thermal conditioning of the components is performed to remove moisture. The thermal conditioning is performed both before and/or after reconditioning. Both bulk components and components attached to PCBs are subjected to thermal conditioning. The thermal conditioning cycle is selected, for example, from IPC/JEDEC J-STD-020 standard based upon the moisture classification set forth by the component manufacturer and the thickness of the components. The moisture classification levels are specified in the data sheet for the particular component by the component manufacturer and are a function of the moisture permeability of the component package material. The thickness of the component may be either measured or obtained from the data sheet for the component.

Standard IPC/JEDEC J-STD-020 provides eight moisture classification levels: 1, 2, 2A, 3, 4, 5, 5A and 6 for electronic components packaged in moisture permeable packages. Thermal profiling is set forth in the JEDEC standard IPC/JEDEC J-STD-020 as a function of the moisture level and the thickness of the IC. For example, recommended bake times, assuming the shelf life has expired, are as follows:

a packages less than or equal to 1.4 millimeters for levels 2A through 5A: bake time ranges from 4 to 14 hours at 125° C. or 5 to 19 days at 40° C.;

package thickness less than or equal to 2 millimeter for levels 2A through 5A: bake time ranges from 18 to 48 hours at 125° C. or 21 to 68 days at 40° C.;

package thickness less than or equal to 4 millimeters for levels 2A through 5A: recommended bake times are 48 hours at 125° C. or 67 or 68 days at 40° C.

Accordingly, components are assumed to be at the expiration of their expected floor life and are grouped according to moisture specification and thickness as specified by the original component manufacturer. The thermal conditioning cycle is then established, based on the moisture classification level and component thickness-for example, as set forth in the IPC/JEDEC J-STD-020 standard or other standard or customer specification-in order to remove moisture from the component packages. For example, for components having a package thickness less than or equal to 2 millimeters and having a moisture classification level between 2A and 5A, as discussed above, the bake times range from 18 to 48 hours at 125° C. An exemplary bake time for such components may be 24 hours at 125° C.

The thermal conditioning cycle can be perfomed utilizing a conventional industrial convection oven, such as a Model CC-095-M-C Series convection oven, available from Blue M Electric of Watertown, Wis. with a Stat-350 Controller, as described in “CC Series Convection Ovens W/Stat-350 Controller; Installation, Operation and Maintenance Manual” published by General Signal Technology Corp., publication 1-69369, REL A, 02/2001, hereby incorporated by reference.

Components are removed from printed circuit boards if necessary in step 28. This step is used to remove any components that have been soldered to a PCB. Such components are removed by re-flow of the solder and removal of the component while the solder is in a liquidous state. The components may be removed by way of a solder rework center, for example, a Model No. IR 500 A/IR 400 A, available from ERSA Lottechnik GmbH, Wentheim, Germany, described in detail in “Operating Instructions IR 500 A/IR 400 A”, published by ERSA Lottechnik GmbH, 02/99, hereby incorporated by reference. More particularly, the PCB is secured within a fixture within the solder rework center and positioned according to the manufacturer's specifications. Solder joints are heated by, for example, IR radiators, to cause solder reflow. Components are then removed by way of, for example, a vacuum pipette.

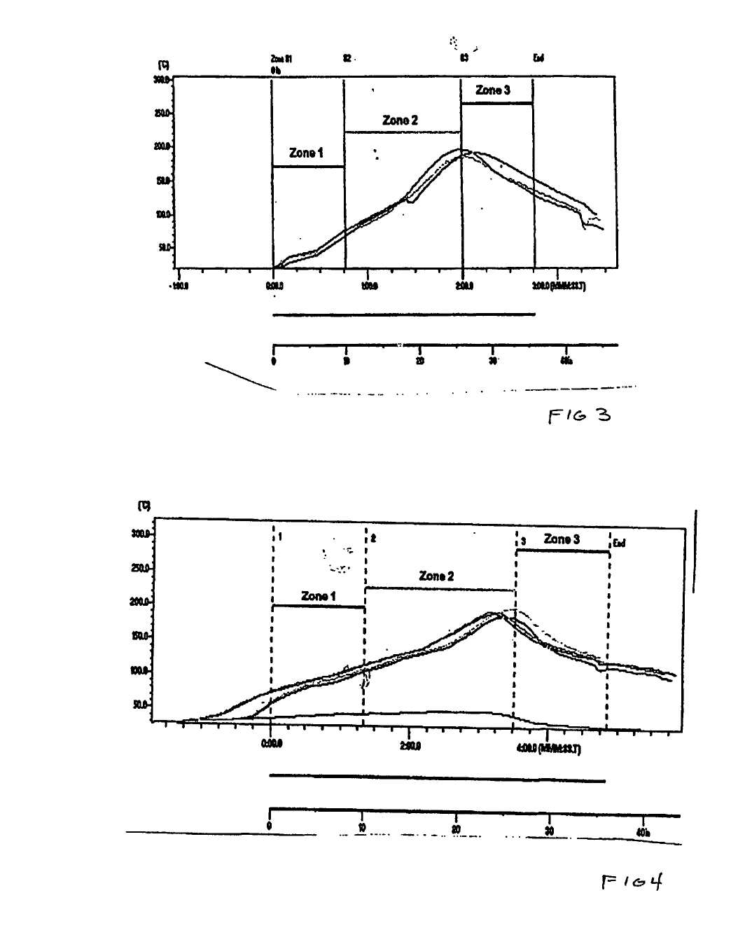

In order to maintain the integrity of the package during component removal, components are removed with a thermal profile in which the peak temperatures are within predetermined limits. Exemplary profiles for component removal are illustrated in FIGS. 3 and 4. These exemplary profiles are based on thermocouples located: on the solder side of the part opposite the leading edge (Zone 1); the top surface of the part (Zone 2); and the solder side of the part on the leading edge (Zone 3). An exemplary thermal profile for a non-SMT component is illustrated in the FIG. 3 and a BGA-type IC in FIG. 4. The thermocouples may be directly attached to the component, for example, with kapton tape.

Table 1 below illustrates an exemplary thermal profile for a non-SMT component.

TABLE 1
MAXIMUM AND MINIMUM TEMPERATURES
IN ° C. FOR A NON-SMT COMPONENT

| Max. Temp | Max. Time | Min. Temp | Min. Time |
|---|---|---|---|
| 200.0 | 1:57.5 | 20.0 | 0:00.00 |
| 197.5 | 2:02.0 | 20.0 | 0:00.0 |
| 196.5 | 2:06.0 | 20.5 | 0:00.0 |

Table 2 illustrates the maximum rate of change of temperature for the thermal profile illustrated in FIG. 3 for each of the three zones.

TABLE 2
MAXIMUM TEMPERATURE RATE OF CHANGE
FOR NON-SMT COMPONENTS

| Zone #1 | Zone #2 | Zone #3 | Zoom Max |
|---|---|---|---|
| Max [+] | Max [+] | Max [+] | Max [+] |
| +1.80 | +2.90 | +0.00 | +2.90 |
| +2.00 | +2.40 | +0.20 | +4.10 |
| +1.90 | +2.70 | +1.20 | +2.70 |

The zoom is the speed or rate of temperature change and the slopes once developed, are maintained by the cyclonic generators inside the oven.

The thermal profile for removing BGA-type IC is illustrated in FIG. 4. Similar to the non-SMT components, the thermal profile for BGA-type components is based on thermocouples located: on the solder side of the part opposite the leading edge (Zone 1); the top surface of the part (Zone 2); and the solder side of the part on the leading edge (Zone 3).

The minimum and maximum temperature profiles for BGA-type components are illustrated in Tables 3 and 4.

TABLE 3
MINIMUM TEMPERATURE PROFILE
FOR REMOVING BGA COMPONENTS FROM PCB

| Minimum Temp. (° C.) | Minimum Time (Minutes) |
|---|---|
| 27.0 | −1:41.5 |
| 28.5 | −1:41.5 |
| 29.5 | −1:22.0 |
| 28.0 | −1:40.0 |
| 27.0 | −1:40.5 |

The minus time is the amount of time the oven is programmed to move the PCB containing the BGA along the conveyor belt before beginning to record data.

TABLE 4
MAXIMUM TEMPERATURE PROFILE FOR
REMOVING A BGA-TYPE COMPONENT FROM A PCB

| Maximum Temp. (° C.) | Minimum Time (Minutes) |
|---|---|
| 193.0 | 3:11.0 |
| 200.0 | 3:26.0 |
| 239.5 | 3:26.0 |
| 187.5 | 3:16.0 |
| 196.0 | 3:09.5 |

The maximum slope or the maximum increase in temperature in the thermal profile for each of the three zones for removing BGA-type components from a PCB is illustrated in Table 5.

TABLE 5
MAXIMUM TEMPERATURE
RATE OF CHANGE FOR BGA-TYPE COMPONENTS

| Zone 1 | Zone 2 | Zone 3 | Zoom |
|---|---|---|---|
| Max [+] | Max [+] | Max [+] | Max [+] |
| +0.70 | +1.20 | +0.00 | +1.20 |
| +1.30 | +1.60 | −0.10 | +1.60 |
| +1.20 | +1.40 | +1.10 | +1.40 |
| +0.80 | +1.30 | −1.30 | +1.30 |

After the components have been removed from the printed circuit boards, the components may again be inspected in step 30 to determine if they are repairable. In particular, it is known that removal of the component from the PCB can result in weakening of the leads during this process. As such, components may be inspected again, as discussed above. If the components are determined to be damaged in step 30, they are discarded and placed on a reject tray in step 32. If the components are found to be in an acceptable condition after being removed from the printed circuit board, the components are reconditioned.

BGA-type components are reconditioned in accordance with the process in steps 32 through 46, while non-SMT components are reconditioned in accordance with the process in steps 48 to 66. After reconditioning in accordance with steps 32-66, all components are optionally cleaned with de-ionized water. In addition, in step 68, all components are optionally baked after reconditioning to remove moisture in accordance with the thermal conditioning cycles discussed in connection with step 26 and step 68. After baking, all reconditioned components are packaged in anti-static trays, tubes or a tape-and-reel or other container per the customer's specifications and then vacuum-packed in anti-static moisture-free bags. Vacuum packing may be accomplished, for example, by way of a Model No. FG2030 vacuum sealer, manufactured by Vander Stahl Scientific Inc. of Wrightwood, Calif. as described in “FG-2000 Series Gas/Flush Retractable Nozzle Vacuum Sealer Operations Manual” published by Vander Stahl Scientific Inc., hereby incorporated by reference. The bags may optionally be bar-coded in step 70 for shipment to the customer in step 72.

As mentioned above, BGA-type component reworking is discussed in connection with steps 34 to 46. Solder coverage of the copper plates on the component is maintained to prevent oxidation. However, in step 34, excess solder is removed from BGA-type IC, for example, by way of a hotplate, for example, a Mirak, series 725-730 hotplate, as manufactured by the Barnsted/Thermal Line Corporation of Dubuque, Iowa, described in detail in “Mirak Hot Plates, Stirrers and Stirring Hot Plate Operational Manual and Parts List”, Document No. LT 727×7, published by Barnstead/Thermolyne Corporation, Jun. 7, 1999, hereby incorporated by reference. More particularly, a flux stone is attached to a pressure hose and placed in a flux basin. The flux basin is filled with flux to cover the flux stone. Power is then applied to the hot plate and the desired temperature, as discussed below, is selected. In accordance with an important aspect of the invention, the solder is absorbed onto a copper sheet in order to prevent oxidation. More particularly, a copper sheet, for example, 6″×6″, with the scintillated side facing up, is placed and flattened onto a vacuum chuck, included with the hot plate. Once the temperature is stabilized at its set point, parts are placed, solder side down, on the copper sheet using a vacuum pen. Using the vacuum pen, the part is lifted over the flux foam so that the solder side of the component receives enough flux to activate the de-soldering process without submerging the part in flux. Pressure may be applied to the component to cause the solder to be absorbed onto the copper sheet. The component may be moved around the copper plate until all of the solder is removed. When no more solder can be absorbed, the component is removed from the hot plate, for example, with the vacuum pen.

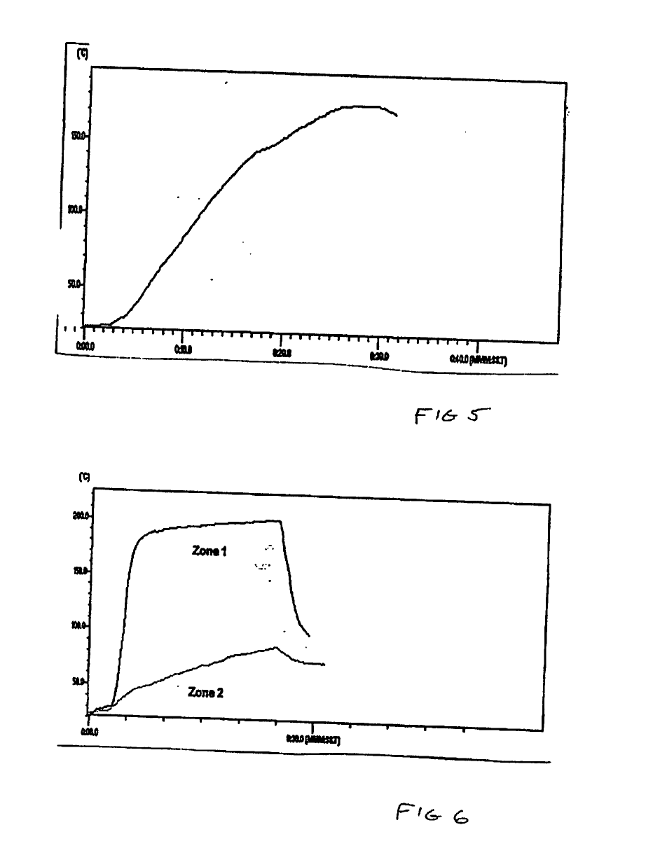

The temperature profile for the solder removal may be, for example, as illustrated in FIG. 5 and Table 6.

TABLE 6
TEMPERATURE PROFILE FOR EXCESS SOLDER
REMOVAL OF BGA COMPONENT

| Max. Temp | | Min. Temp. | |
|---|---|---|---|
| ° C. | Max. Time | ° C. | Min. Time |
| 177.0 | 0:27.6 | 22.5 | 0:00.0 |

After the excess solder is removed in step 34, BGA components are inspected for the following: popcorn (may be viewed with or without a magnifier), splitting/cracking, physical damage, delamination, charring/burning, lifted pads, broken traces and exposed copper within the sphere matrix.

BGA components passing inspection are loaded onto a fixture or chuck and passed to a BGA re-balling system machine, for example, as manufactured by QTA Machine of Irvine, Calif. and as discussed in detail in “Owner's Manual BGA Re-balling System” by QTA Machine, hereby incorporated by reference. The reballing process is initiated by installing a stencil of the solder sphere matrix on the fixture or chuck. Solder paste is applied to a portion of the stencil and spread evenly, for example, with a spatula. A sufficient number of solder spheres are swept into all of the holes in the stencil containing the solder paste. The solder spheres are then pressed generally into the paste. The excess spheres are removed. Subsequently, the chuck with the stencil are inspected for sphere presence and sphere offset. After the BGA IC component has been re-balled, the solder spheres are re-flowed, for example, by way of a Novastar Re-flow Oven by Novastar Technologies, Inc. of Huntingdon Valley, Pa., Model No. 1200, as discussed in detail in “Instruction Manual: Model 1200 Re-flow Solder Oven”, by Novastar Technologies, Inc. The thermal profile used for re-flow is selected in accordance with the manufacturer's specifications.

After the solder spheres are re-flowed, the component is inspected for ball offset and ball presence. If not, steps 34 to 40 are repeated. If, after the re-flow of the solder spheres is complete and the component is found acceptable, excess flux and/or paste is cleaned from the component in step 42, for example, by way of an Aqueous Cleaning System Model No. 6300. After cleaning, the BGA components are dried, for example, 4 hours and brushed with a lint-free plastic bristle brush. The component is again inspected in step 44 for ball presence and ball offset. If the component is found unacceptable, Steps 32 to 44 are repeated. If the component is found to be acceptable, the component is cleaned and final-baked and packaged as discussed above in steps 68 through 72.

As mentioned above, steps 48 through 66 relate to leaded components. In step 50, such leaded components are visually inspected to determine whether there is excess solder on the leads. If so, the excess solder is removed in step 54 by way of the hot plate, as discussed above, utilizing the temperature profile illustrated in FIG. 6 and Tables 7 and 8. The temperature profile is based on thermocouples located on the solder side of the part (Zone 1) and the top surface of the part (Zone 2).

TABLE 7
THERMAL PROFILE FOR SOLDER REMOVAL
FROM LEADED COMPONENTS

| Min. Temp | |
|---|---|
| ° C. | Min. Time |
| 23.0 | 0:00.0 |
| 23.5 | 0:00.0 |

TABLE 8
MAXIMUM TEMPERATURE PROFILE FOR
SOLDER REMOVAL FROM LEADED
COMPONENTS

| Max. Temp | |
|---|---|
| ° C. | Max. Time |
| 200.0 | 0:24.0 |
| 87.5 | 0:24.8 |

After the excess solder is removed, excess flux and/or paste is removed from the component in step 56 as discussed above. The system then proceeds to step 58. Alternatively if, upon inspection, no excess solder is found on the lead and the component is found to be clean, the component proceeds directly from step 48 to step 58.

In step 58, the component leads are re-formed-for example, by a lead re-forming MLCS-2 manual reconditioner, available from Fancort Industries, Inc. of West Caldwell, N.J., which restores lead configurations to JEDEC specifications. The leads are reconditioned in accordance with the recommendation of the manufacturer of the lead reforming manual reconditioner. After the leads have been re-formed, the component is inspected in step 60, for example, by way of a Model LRSK Inspection Kit, also available from Fancort Industries, Inc. If not, the component is evaluated to determine if it is repairable. Components with weakened, damaged or broken leads are placed in a reject tray in step 66. Components that are deemed to be repairable repeat steps 58 through 62. Once the leaded component is determined to be acceptable, the component is cleaned, baked and vacuum-sealed in steps 68 and 70 and shipped to the customer in Step 72.

Obviously, many modifications and variations of the present invention are possible in light of the above teachings. For example, thus, it is to be understood that, within the scope of the appended claims, the invention may be practiced otherwise than as specifically described above.

What is claimed and desired to be secured by Letters Patent of the United States is:

We claim:

1. A process for reconditioning electronic components having electrical connections, the process comprising the steps of:
(a). inspecting the external electrical connections on said electronic components according to a predetermined criteria.
(b). thermally conditioning said components to remove moisture; and
(c). reconditioning said electrical connections.

2. The process as recited in claim 1, wherein the step of thermally conditioning of said electronic components is performed before the step of reconditioning.

3. The process as recited in claim 1, wherein the step of thermal conditioning of said electronic components is performed after the step of reconditioning.

4. The process as recited in claim 1, wherein the step of thermal conditioning is performed before and after the step of reconditioning.

5. The process as recited in claim 1, further including the step of vacuum packaging of components after they have been reconditioned.

6. The process as recited in claim 1, further including the step of removing electronic components from a printed circuit board (PCB).

7. The process as recited in claim 6, wherein said removing step is performed after the thermal conditioning step.

8. The process as recited in claim 1, wherein said step of reconditioning said electrical connections comprises reworking electrical leads on leaded electronic components.

9. The process as recited in claim 8, further including the step of removing excess solder from said electrical leads before said electrical leads are reconditioned.

10. The process as recited in claim 8, further including the step of removing excess solder and paste from the electrical leads before said electrical leads are recommended.

11. The process as recited in claim 1, wherein said step of reconditioning said electrical connections comprises reballing solder spheres on ball grid array type components.

12. The process as recited in claim 11, wherein said reballing step comprises:
removing the solder spheres and excess solder from the electronic component;
replacing the removed solder spheres with solder paste and spheres; and
reflowing the solder spheres.

13. The process as recited in claim 12, further including the step of cleaning excess solder and paste from the electronic component.

14. The process as recited in claim 6, wherein the step of removing electronic components from said PCB is performed using a predetermined temperature profile.

15. The process as recited in claim 10, wherein the step of removing excess solder is performed using a predetermined temperature profile.

16. The process as recited in claim 13, wherein the step of removing excess solder is performed using a predetermined temperature profile.

17. The process as recited in claim 1, wherein said thermal profiling step is conducted to meet a predetermined standard.

18. The process as recited in claim 1, said thermal profiling step is conducted to meet JEDEC standards.

19. The process as recited in claim 1, wherein said thermal conditioning step comprises baking said electronic components at 125° C. for 24 hours.

20. The process as recited in claim 1, wherein the thermal conditioning is selected as a function of the moisture classification level and thickness of the electronic component.

21. A system for reconditioning electrical connections on electronic components, the system comprising:
means for reconditioning said electrical connections; and
means for thermal conditioning said electronic components to remove moisture from said electronic components.

22. The sytem as recited in claim 21, wherein said electrical components comprise leaded components with external electrical leads.

23. The system as recited in claim 21, wherein said electrical components comprise ball grid arrays (BGA).

24. The system as recited in claim 23, wherein said thermal conditioning means includes means for thermally baking said BGA components to a predetermined thermal profile.

25. The system as recited in claim 24, wherein said thermal conditioning cycle is selected from a predetermined standard.

26. The system as recited in claim 25, wherein said predetermined standard is a JEDEC standard.

27. A process for selecting a thermal conditioning cycle for use in removing moisture for a moisture permeable electronic component to be reconditioned:
(a). determining the moisture classification level of said electronic component to be reconditioned;
(b). determining the thickness of said electronic component to be reconditioned; and
(c). selecting a thermal profile as a function of the moisture classification level and said thickness of said component to be reconditioned.

28. The process as recited in claim 27, wherein the moisture classification level is obtained from manufacturer's data sheets for said electronic component to be reconditioned.

29. The process as recited in claim 27, wherein the thickness of said electronic component to be reconditioned is obtained from manufacturer's data sheets for said component.

30. The process as recited in claim 27, wherein step (c) comprises selecting a thermal profile from a standard.
